(19) United States
(12) Patent Application Publication
(10) Pub. No.: US 2024/0063755 A1
(43) Pub. Date: Feb. 22, 2024

(54) PHOTOVOLTAIC THERMAL SYSTEM FOR COUPLING TO SOLAR PANELS

(71) Applicant: PVT Clean Energy LLC, Poughkeepsie, NY (US)

(72) Inventors: Mehdi Zadshir, New York, NY (US); Huiming Yin, Alpine, NJ (US); Frank Pao, Boston, MA (US); Brendan De Leon, Verona, NJ (US)

(21) Appl. No.: 18/474,816

(22) Filed: Sep. 26, 2023

Related U.S. Application Data
(60) Provisional application No. 63/377,057, filed on Sep. 26, 2022.

(51) Int. Cl. H02S 40/42; H02S 30/10; F24S 10/70; F24S 80/30

(52) U.S. Cl. CPC H02S 40/425; H02S 30/10; F24S 10/70; F24S 80/30; F28D 15/02

(57) ABSTRACT

A photovoltaic thermal (PVT) system for coupling to a solar panel, includes: thermal parts, including: a copper sheet comprising a first side and a second side opposite the first side, where the first side is for coupling to a back of the solar panel; at least a first plurality of heat pipes coupled to the second side of the copper sheet; and at least a first manifold coupled to ends of the first plurality of heat pipes; and an insulation layer coupled to the thermal parts, where if the thermal parts are coupled to the back of the solar panel, the copper sheet receives heat transferred from the solar panel and transfers the heat to the first plurality of heat pipes, and the first plurality of heat pipes transfers the heat to the first manifold. The PVT system manages the temperature of the solar cells in the solar panel.

### CROSS-REFERENCE TO RELATED APPLICATIONS

The present application claims priority to U.S. Provisional Patent Application Ser. No. 63/337,057, entitled “Building Integrated Photovoltaic Thermal Systems”, filed on Sep. 26, 2022. The foregoing application is incorporated herein by reference in its entirety.

### TECHNICAL FIELD

The present invention relates to photovoltaic systems, and more particularly to a photovoltaic thermal system used in combination with a solar panel.

### BACKGROUND ART

Solar panels convert solar energy into electricity. Currently, crystalline silicon photovoltaic (PV) cells are the most common type of solar cells that are used in solar panels. In addition to the conversion of sunlight to electricity, all solar cells convert parts of the solar energy into heat, which results in increasing the module's temperature. Since solar cells are sensitive to temperatures, an increase in the cell's temperature reduces the bandgap of the silicon semiconductor. This results in a significant reduction in the efficiency and the consequent output of the PV system and over time, degrades the materials which shortens the expected life span of the solar panels. On the other hand, conventional rooftop solar panels are placed as a structure on the roof of the house. Installing such systems requires puncturing the roof, which risks water leakage due to rain.

### SUMMARY OF THE EMBODIMENTS

In one example, a photovoltaic thermal system for coupling to a solar panel, includes: thermal parts, including: a copper sheet comprising a first side and a second side opposite the first side, where the first side is for coupling to a back of the solar panel; at least a first plurality of heat pipes coupled to the second side of the copper sheet; and at least a first manifold coupled to ends of the first plurality of heat pipes; and an insulation layer coupled to the thermal parts, where if the thermal parts are coupled to the back of the solar panel, the copper sheet receives heat transferred from the solar panel and transfers the heat to the first plurality of heat pipes, and the first plurality of heat pipes transfers the heat to the first manifold.

In another example, a system, includes: a solar panel including a plurality of solar cells; and a photovoltaic thermal system coupled to a back of the solar panel, the photovoltaic thermal system including: a copper sheet including a first side and a second side opposite the first side, where the first side is for coupling to a back of the solar panel; a plurality of heat pipes coupled to the second side of the copper sheet; and a first manifold coupled to ends of the first plurality of heat pipes and positioned proximate to a top edge of the solar panel; and an insulation layer coupled to the thermal parts, where the copper sheet receives heat transferred from the solar panel and transfer the heat to the first plurality of heat pipes, and the first plurality of heat pipes transfers the heat to the first manifold.

### BRIEF DESCRIPTION OF THE DRAWINGS

The foregoing features of embodiments will be more readily understood by reference to the following detailed description, taken with reference to the accompanying drawings, in which:

FIG. 1 illustrates a top perspective view of a PVT system in combination with a solar panel, according to a first embodiment.

FIG. 2 illustrates an exploded view of a PVT system in combination with a solar panel, according to the first embodiment.

FIG. 3 illustrates a bottom perspective view of the thermal parts, according to the first embodiment.

FIG. 4 illustrates an exploded view of the thermal parts, according to the first embodiment.

FIG. 5 illustrates a bottom perspective view of the thermal parts, according to a second embodiment.

FIG. 6 illustrates a side view of a manifold positioned at an edge of the solar panel, according to the second embodiment.

FIG. 7 illustrates a bottom perspective view of the thermal parts, according to a third embodiment.

FIG. 8 illustrates a bottom perspective view of the thermal system, according to a fourth embodiment.

FIG. 9 illustrates a side view of the thermal system, according to a fourth embodiment.

FIG. 10 illustrates a close-up perspective view of a coupling between a heat pipe and a manifold, according to a fifth embodiment.

FIG. 11 illustrates a close-up exploded view of a coupling between a heat pipe and a manifold 1001, according to a fifth embodiment.

FIG. 12 illustrates a cross-sectional view of a coupling between a heat pipe and a manifold, according to a fifth embodiment.

FIG. 13 illustrates a perspective view of a wick-structure flat heat pipe, according to a sixth embodiment.

FIG. 14 illustrates a perspective view of a round evacuated tube, according to the sixth embodiment.

FIGS. 15A and 15B illustrate differences between the wick-structure flat heat pipe and the round evacuated tube.

FIG. 16 illustrates a perspective view of a PVT system attached to a solar panel, according to a seventh embodiment.

FIG. 17 illustrates a bottom exploded view of the thermal parts used with a solar panel, without showing an insulating layer, according to the seventh embodiment.

FIG. 18 illustrates a first configuration of a plurality of PVT systems.

FIG. 19 illustrates a second configuration of a plurality of PVT system.

FIG. 20 illustrates an example system that utilizes the PVT system.

FIG. 21 illustrates an example ecosystem that uses the PVT system.

FIG. 22 illustrates the example ecosystem as a solar geothermal house with a pool.

### DETAILED DESCRIPTION OF SPECIFIC EMBODIMENTS

Reference in this specification to “one embodiment”, “an embodiment”, “an exemplary embodiment”, “some embodiments”, or “a preferred embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments. In general, features described in one embodiment might be suitable for use in other embodiments as would be apparent to those skilled in the art.

It should be understood that the exemplary embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from their spirit and scope.

Embodiments of the present invention provide a photovoltaic thermal (PVT) system that may be used in combination with a solar panel. The PVT system harvests the heat captured by the solar panel, such that the temperature of the silicon cells in the solar panel may be managed. The PVT system is connected to a fluid circulation system, where stored heat may be sent into a fluid flow for storage and later use. By managing the temperature of the silicon cells, the PVT system allows the solar panel to operate with a higher efficiency and higher consequent output over time than solar panels used without the PVT system. Managing the temperature of the silicon cells further reduces the degradation of the materials of the solar panel, which extends the life span of the solar panel. In one example embodiment, the solar panels with the PVT systems may be integrated into a building to function as a roof or façade of the building instead of being a structure that is placed on top of or onto the roof or wall. Being building integrated, no puncturing of the roof or wall is required for installation, which avoids the risk of water leakage that may result from such puncturing. The PVT system may be connected to any solar panel, regardless of whether the solar panel is building integrated.

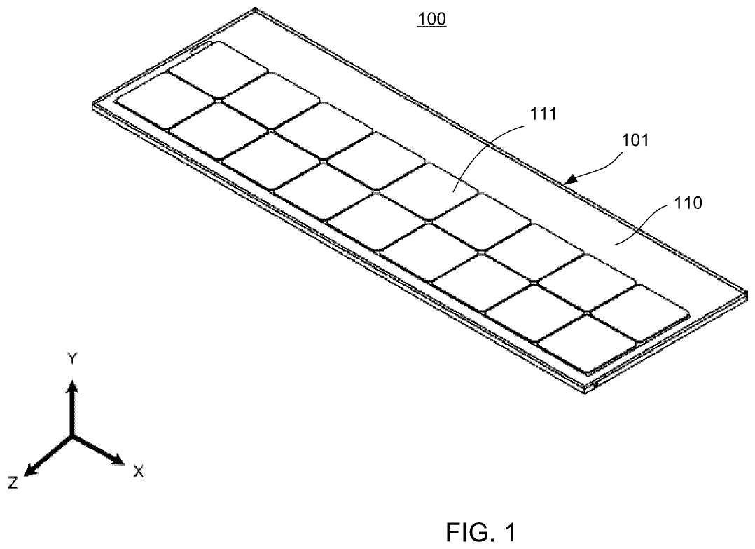

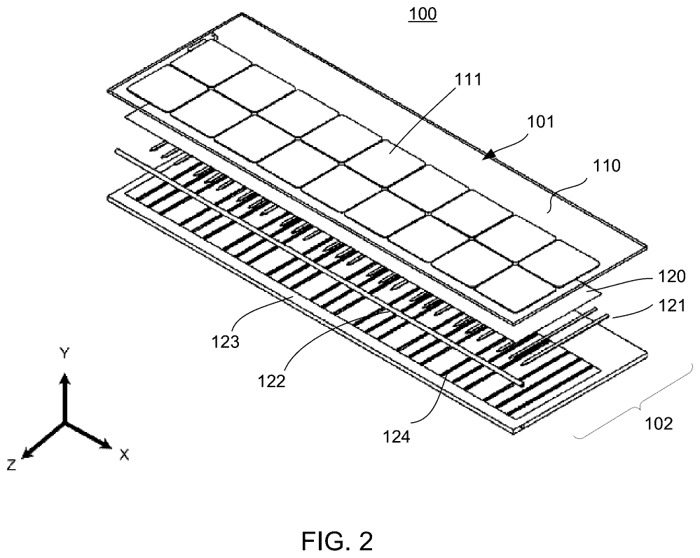

FIGS. 1 and 2 illustrate a top perspective view and an exploded view, respectively, of a PVT system 100 in combination with a solar panel 101, according to a first embodiment. The solar panel 101 may include layers of glass, a plurality of solar cells 111, wiring (not shown), and an ethylene vinyl acetate (EVA) sheet (not shown). A backing material (not shown) is coupled to the back of the solar panel 101. The PVT system 100 includes thermal parts 102 that may be coupled to the back of the solar panel 101. The thermal parts 102 include a copper sheet 120, a plurality of heat pipes 121, at least one manifold 122, and an insulating layer 123. The manifold 122 may be a cross-linked polyethylene (PEX) manifold. Other thermally insulative piping may be used for the manifold 122, where fluid is allowed to flow within and the fluid includes an anti-freeze solution, such as water and glycol. The dimensions of the copper sheet 120 may approximately match the dimensions of the plurality of solar cells 111 or the dimensions of the solar panel 101. The manifold 122 includes a plurality of entrances. Each heat pipe 121 includes at least one bulb on at least one end. The manifold 122 may be positioned such that the bulbs of the heat pipes 121 are coupled to the entrances of the manifold 122, such that fluid that flows through the interior of the manifold 122 in a laminar flow will contact the bulbs, carrying heat away from the bulbs to a heat storage facility (not shown). A thermally conductive adhesive may be used to couple the thermal parts 102 together. The solar panel 101 and the thermal parts 102 are coupled to an insulating layer 123, with resultant cavities 124 formed by the thermal parts 102. The insulating layer 123 is molded over the back of the solar panel 101 and over the thermal parts 102, securing the thermal parts 102 to the back of the solar panel 101. The material of the insulating layer 123 has a low thermal conductivity and prevents heat from being released into the surrounding environment. An example material of the insulation layer 123 may include an insulating foam. For example, the insulating layer 123 may include an expandable polyurethane foam. For another example, the insulating layer 123 may include foam concrete, which is formed from a combination of CO₂, cement paste, glass fibers, and a foaming solution. A foaming method utilizing these materials may be performed twice in order to control the size of the bubbles, which are then stabilized with a silicone-based surfactant, and poured into a mold surrounding the solar panel 101, creating a layer of approximately 0.4-1 inches over a backsheet (not shown), the copper sheet 120, the heat pipes 121, and the manifold 122. The insulating layer 123 protects the thermal parts 102 within, thermally insulating the thermal parts 102, and adhering the thermal parts 102 in place. In one example, copper has a thermal conductivity of 385 W/m·K. By using a sheet of copper 120, the rate at which heat can be transferred away from the solar panel 101 increases significantly when compared to the conventional method of airflow, with air's thermal conductivity being 0.25 W/m·K at 20° C. The thermal properties of copper works in conjunction with the remainder of the PVT system 100, conducting heat into the heat pipes 121 to account for their smaller surface area compared to the copper sheet 120 and taking advantage of the higher thermal conductivity of the heat pipes 121 at 1500 W/m·K. In this example, the heat pipes 121 have a working temperature between 20° C. and 150° C., allowing the heat pipes 121 to keep the solar panel 101 within a desired temperature range while preventing thermal contraction of the glass in the solar panel 101 due to excessive colling.

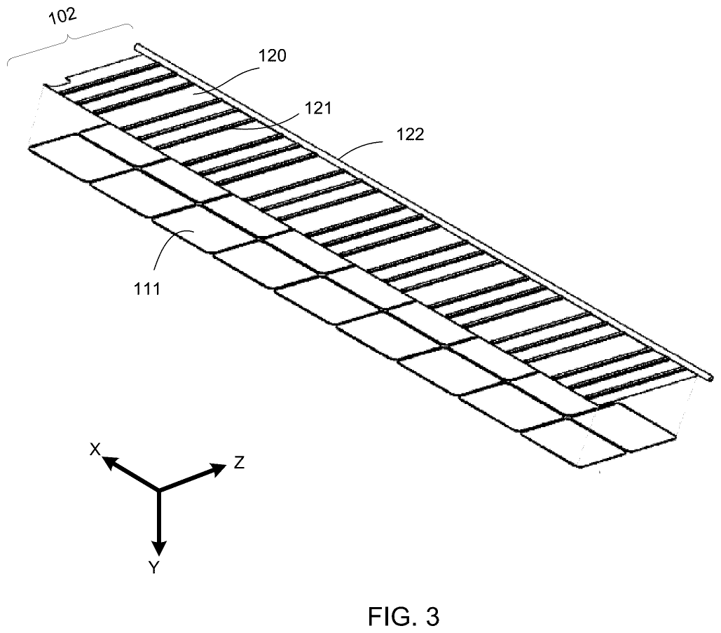

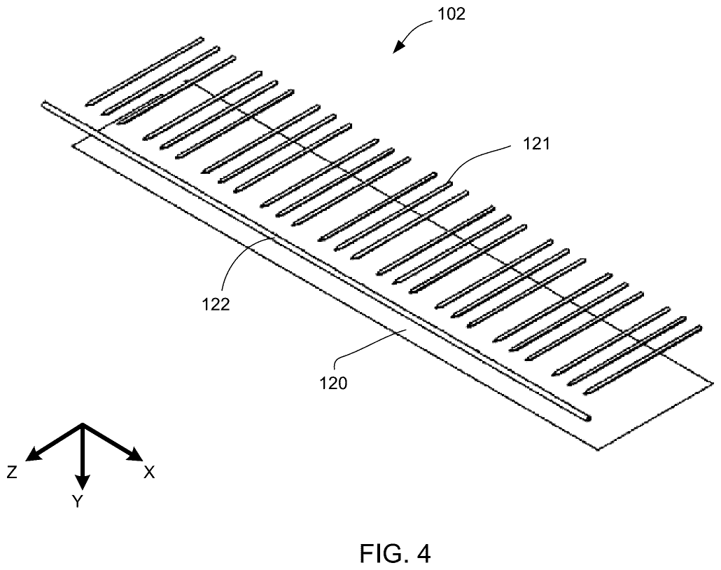

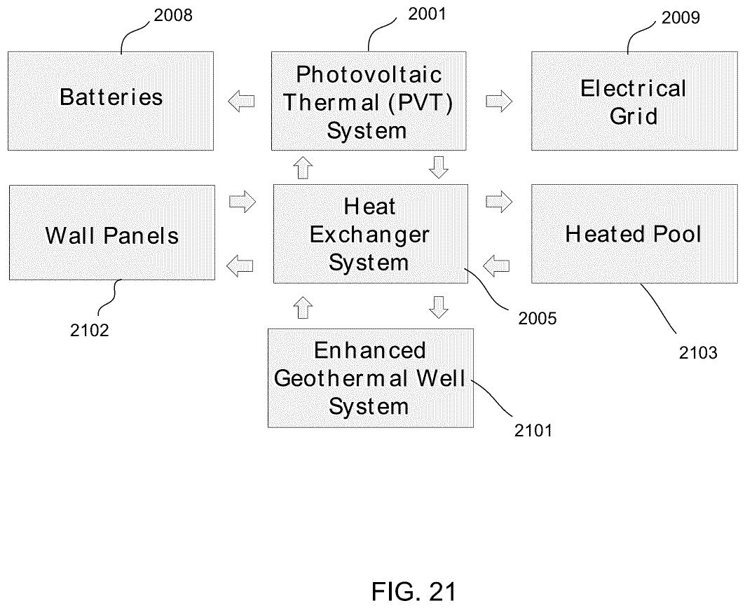

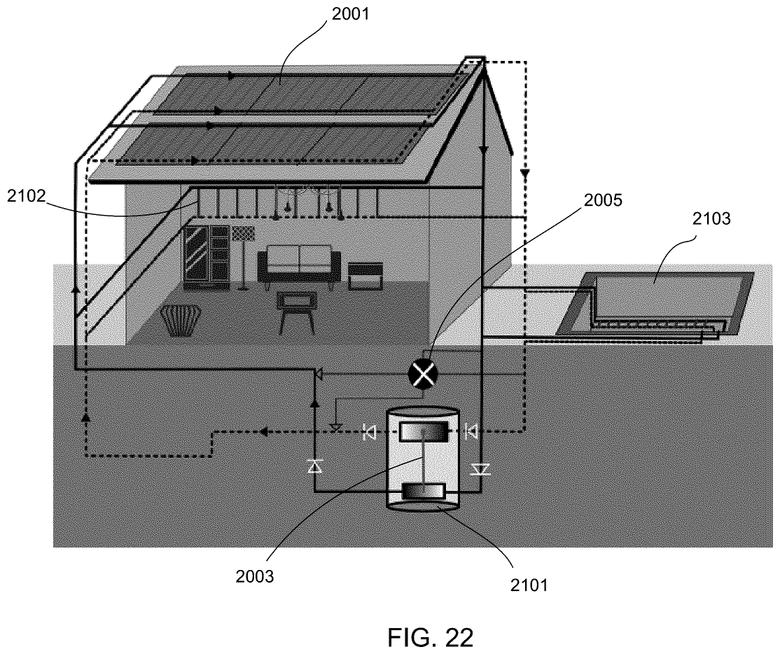

FIGS. 3 and 4 illustrate a bottom perspective view and an exploded view, respectively, of the thermal parts 102, according to the first embodiment. In one example, the dimensions of the copper sheet 120 substantially match the dimensions of the solar panel 101. The solar cells 111 generate heat during their exposure to the sun and while generating electricity. By having the dimensions of the copper sheet 120 approximately match the dimensions of the solar panel 101, the heat may be efficiently transferred from the entire area encompassed by the solar cells 111 to the copper sheet 120. The heat is then transferred from the copper sheet 120 to the heat pipes 121, and from the heat pipes 121 to the manifold 122. The heat pipes 121 may be arranged to maximize the amount of heat captured from the solar cells 111. For example, as illustrated in FIG. 3, the solar cells 111 may be arranged in straight rows and columns, and the heat pipes 121 may be arranged in sets, The number of heat pipes in each set may be based on a target managed temperature for the solar cells 111. For example, a set may include three heat pipes, with each set of three heat pipes positioned to capture heat from a column of solar cells 111. Each set of heat pipes may be placed such that one end is flush with a bottom area of the copper sheet 120 and the solar cells 111. Other arrangements of the solar cells 111 may be used, and the heat pipes 121 may be arranged to maximize the heat capture from this arrangement. Although the thermal parts 102 are described with a copper sheet 120, a sheet composed of other heat conductive material may also be used. In this embodiment, the manifold 122 is positioned proximate to a top edge of the solar cells 111. When installed on a building, the manifold 122 may be positioned such that heated vapor in the heat pipes 121 moves upward towards the manifold 122, transferring heat from the vapor to the fluid within the manifold 122. The heated fluid within the manifold 122 then flows to other systems, as described further below with reference to FIGS. 21 and 22. The vapor in the heat pipes 121 then condenses into a fluid in the bulbs of the heat pipes 121. The fluid in the bulbs of the heat pipes 121 then flows downwards along the heat pipes 121, to be vaporized again.

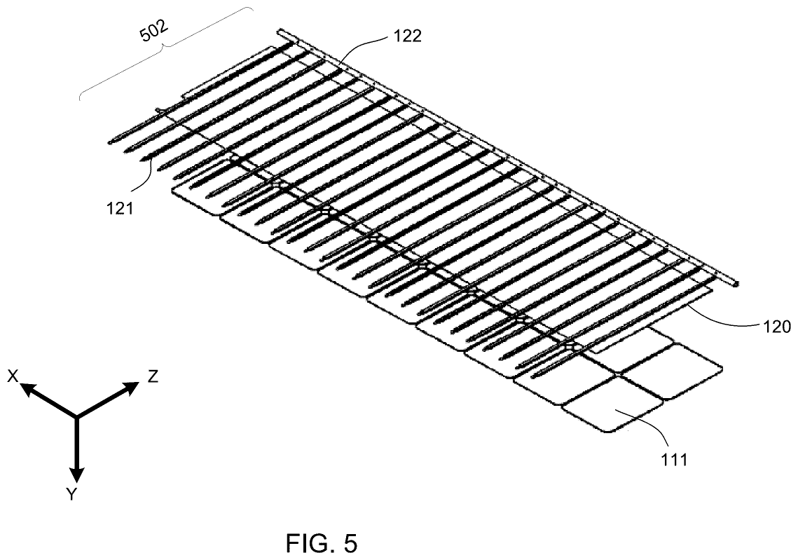

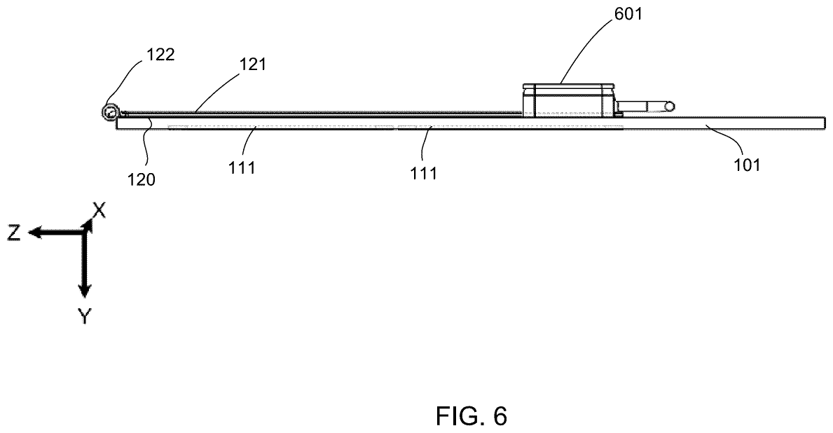

FIG. 5 illustrates a bottom perspective view of the thermal parts 502 according to a second embodiment. The manifold 122 in the second embodiment is positioned proximate to a top edge of the solar panel 101, rather than the edge of the solar cells 111. A plurality of heat pipes 521 are coupled to the manifold 122 in the same manner as described above with reference to the first embodiment, with the heat pipes 521 having longer lengths that accommodate the placement of the manifold 122. This position of the manifold 122 allows for a greater amount of the surface area of the bulbs of the heat pipes 521 to be exposed to the fluid flowing within the manifold 122 than if the manifold 122 is positioned proximate to the edge of the solar cells 111. FIG. 6 illustrates a side view of manifold 122 positioned at an edge of the solar panel 101, according to the second embodiment. The side view includes a view of a junction box 601 containing wirings (not shown) coupled to the solar panel 101.

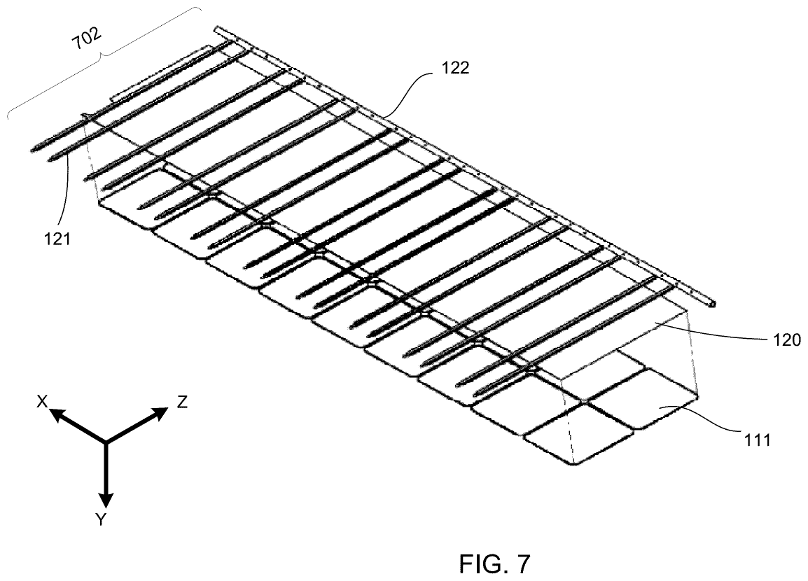

FIG. 7 illustrates a bottom perspective view of the thermal parts 702, according to a third embodiment. In the third embodiment, the heat pipes 121 are arranged in sets of two, with each set of two heat pipes positioned to capture heat from a column of solar cells 111. The heat pipes 121 couple to the manifold 122 in the same manner as described above, with reference to the first embodiment. Groups of two heating pipes 121 may be used when the heat flux out of the solar panel 101 is at a level where the sets of three heat pipes 121 are not necessary. By reducing the number of heat pipes 121 in each set without significantly reducing efficiency, a solar panel 101 that is used with the thermal parts 102 may be lighter in weight. Further, there may be less labor and complexity for the installation of the solar panel 101 with the thermal parts 702.

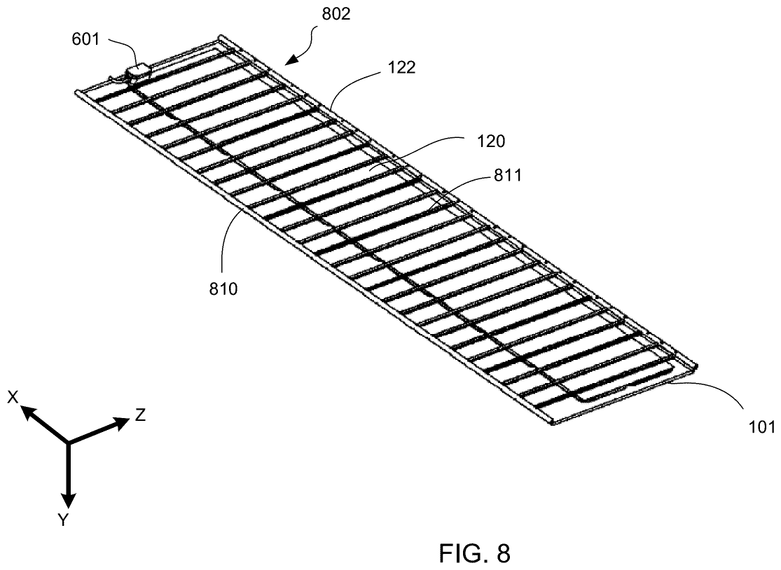

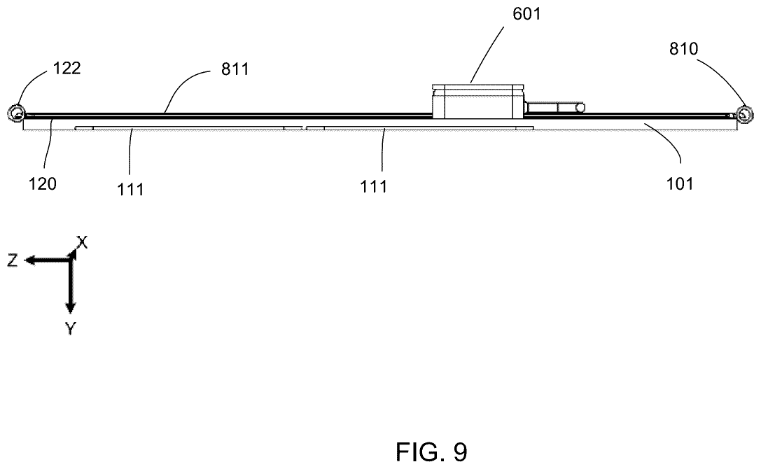

FIGS. 8 and 9 illustrate a bottom perspective view and a side view, respectively, of the thermal system, according to a fourth embodiment. In the fourth embodiment, the thermal parts 802 includes two manifolds, with a first or top manifold 122 positioned proximate to a top edge of the solar panel 101, and a second or bottom manifold 810 positioned proximate to a bottom edge of the solar panel 101. Each of the heat pipes 811 include two bulbs, one at each end. One ends of the heat pipes 811 couple to the top manifold 122, and the other and opposite ends of the heat pipes 811 couple to the bottom manifold 810. The bulbs at each end of the heat pipes 811 allows heat to be exchanged with the top and bottom manifolds 122, 810. By positioning the top and bottom manifolds 122, 811 at the top and bottom edges of the solar panel 101, the lengths of the heat pipes 811 may capture heat along the entire length of the solar cells 111. When installed on a building, the top manifold 122 captures heat in the manner described above with reference to the first embodiment. The bottom manifold 810 is positioned to deliver heat to the heat pipes 811. Warm or hot fluids may flow through the bottom manifold 810. The heat from the fluids in the bottom manifold 810 is transferred to the heat pipes 811 via the bulbs at the bottom end of the heat pipes 811. The heat causes vapor in the heat pipes 811 to move upwards towards the top manifold 122. The movement of the vapor in the heat pipes 811 transfer heat to the copper sheet 120, which in turn transfers heat to the solar panel 101. The heat transferred to the solar panel 101 may melt any snow which has settled onto the solar panel 101, allowing the solar cells 111 to be exposed to the sun.

Referring again to FIGS. 5 and 7, the manifold 122 may compare a tube with a plurality of holes. The manifold 122 may be positioned at an angle to allow for the bulbs of the heat pipes 121 to be inserted with a fit such that a variety of thermally insulative adhesives and sealants can be used to ensure that the fluid flowing within the manifold 122 does not leak. Alternatively, a manifold with socket-type interfaces may be used to allow a frictional contact with the bulbs of the heat pipes 121 and simplify installation, as described further below.

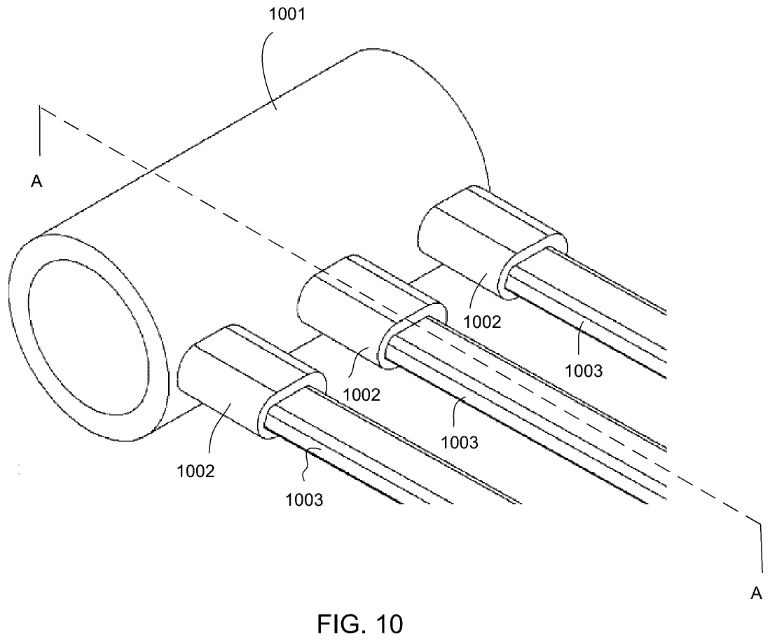

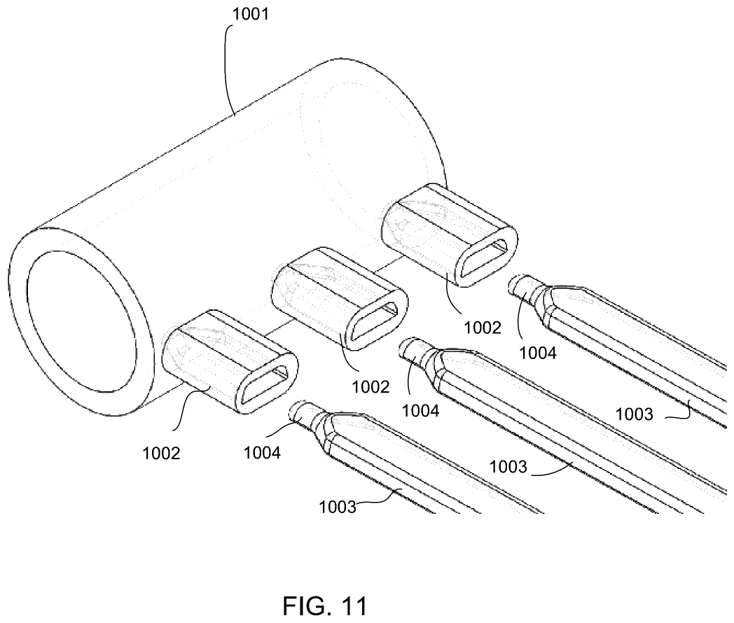

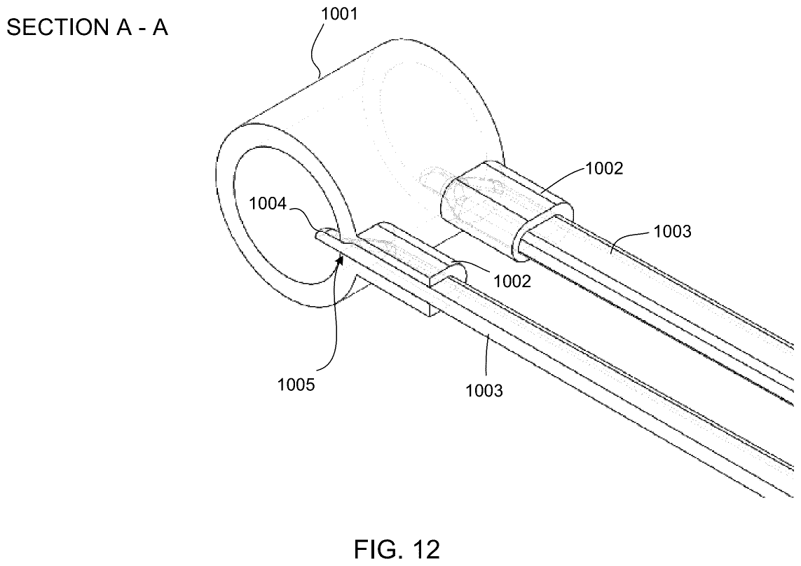

FIGS. 10, 11, and 12 illustrate a close-up perspective view, a close-up exploded view, and a cross-sectional view, respectively, of a coupling between a heat pipe 1003 (e.g., heat pipes 121 and/or 811) and a manifold 1001 (e.g., manifolds 122 and/or 810), according to a fifth embodiment. The manifold 1001 includes a plurality of guiding channels 1002 placed along the length of the manifold 1001, with a waterproof fitting entrance at the intersection 1005 of a bulb 1004 of the heat pipe 1003 and the manifold 1001 in order to allow for the heat pipe 1003 to mechanically snap within, removing the need for an adhesive. Thus, a “dry” plug-in heat pipe 1003 may be used in which the connections are “plug-and-play”, easing installation or replacement of the heat pipe 1003.

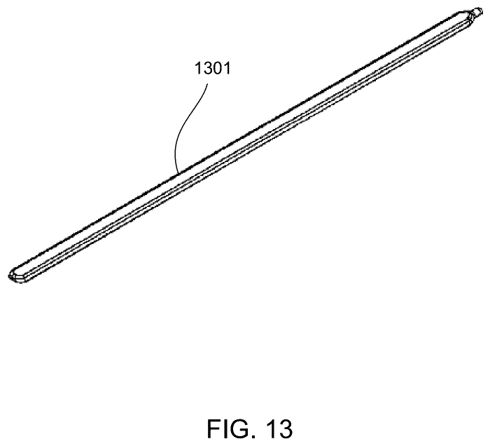

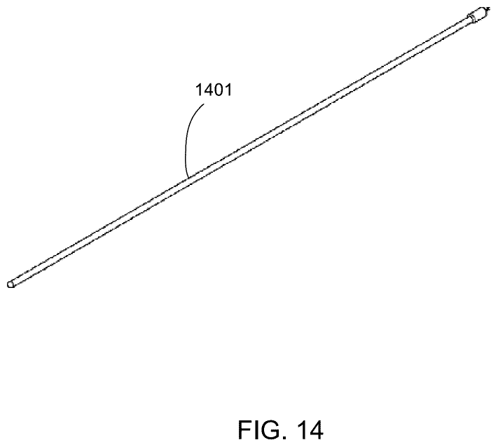

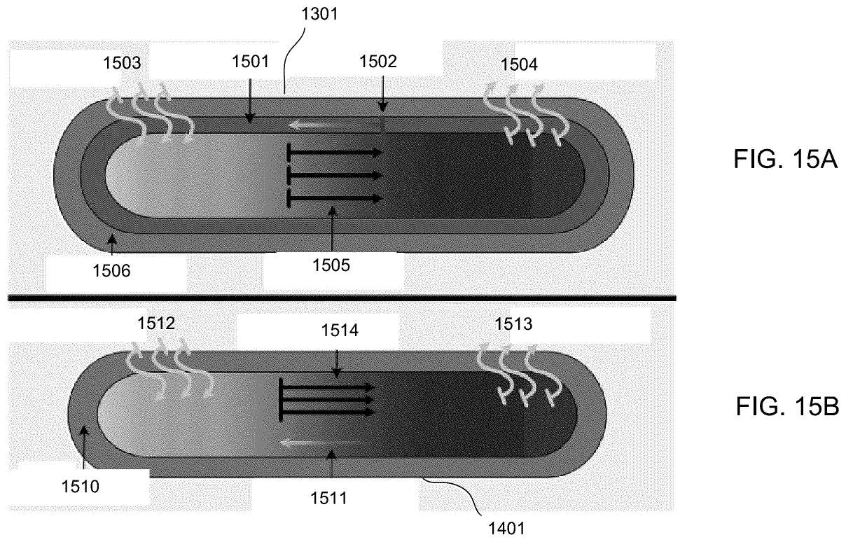

FIG. 13 illustrates a perspective view of a wick-structure flat heat pipe 1301, according to a sixth embodiment. The heat pipes 121 and/or 811 may be composed of a wick-structure flat heat pipe 1301. In some embodiments, the heat pipes 121 and/or 811 may be composed of a round evacuated tube, as illustrated in FIG. 14. In other embodiments, a combination of wick-structure flat heat pipes and evacuated tubes may be used to increase the thermal output of the PVT system 100. FIGS. 15A and 15B illustrate differences between the wick-structure flat heat pipe 1301 and the round evacuated tube 1401. Referring FIG. 15A, the wick-structure flat heat pipe 1301 includes a capillary structure 1501 along the inner wall of the heat pipe 1301 used to transport a condensed fluid 1502 from an evaporator section 1503 to a condenser section 1504. At the evaporator section 1503, heat turns the liquid 1502 to vapor 1505, which travels toward the condenser section 1504, where the bulb is in contact with the manifold 122. At the condenser section 1504, the heat is transferred through a copper exterior 1506 to the fluid in the manifold 122. The vapor cools, turns back to liquid, and returns to the evaporator section 1503. This cycle of reheating and cooling continuously repeats. Referencing FIG. 15B, the round evacuated tube 1401 includes a hollow copper tube 1510 containing a small quantity of a liquid 1511 (such as alcohol/water) with low pressure and some anti-corrosion additives. a vacuum inside the tube 1510 enables the liquid 1511 to vaporize at very low temperatures. When the tube 1510 is exposed to heat at the bottom portion 1512 of the tube 1510, the liquid 1511 turns into vapor 1514, which rises to the top portion 1513 of the tube 1510 and travels upward toward a top bulb (not shown), where the bulb is in contact with the manifold 122. When the vapor 1514 inside the sealed tube 1510 comes in contact with the lower temperature fluid of the manifold 122, heat from the vapor 1514 is transferred to the fluid in the manifold 122. The vapor 1514 then cools and condenses back to the liquid 1511. The liquid 1511 flows to the bottom portion 1512 of the tube 1510, and this cycle of reheating and cooling continuously repeats.

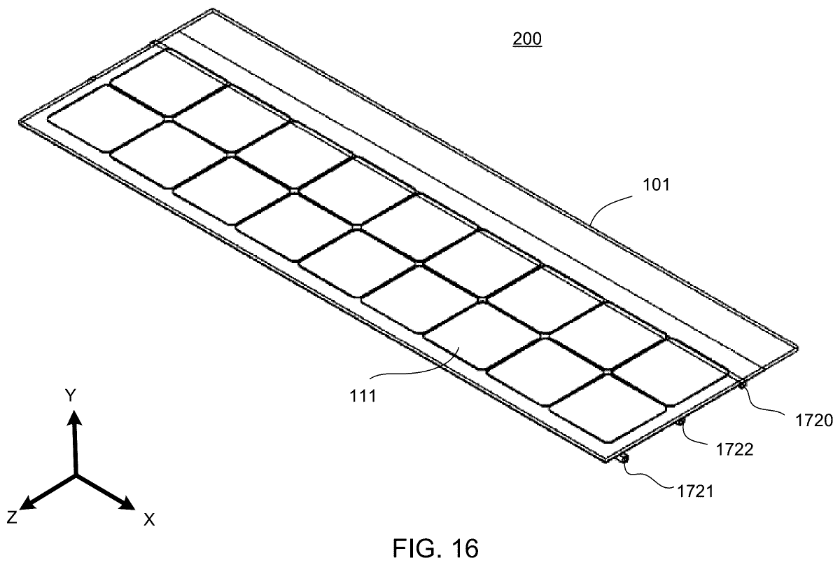

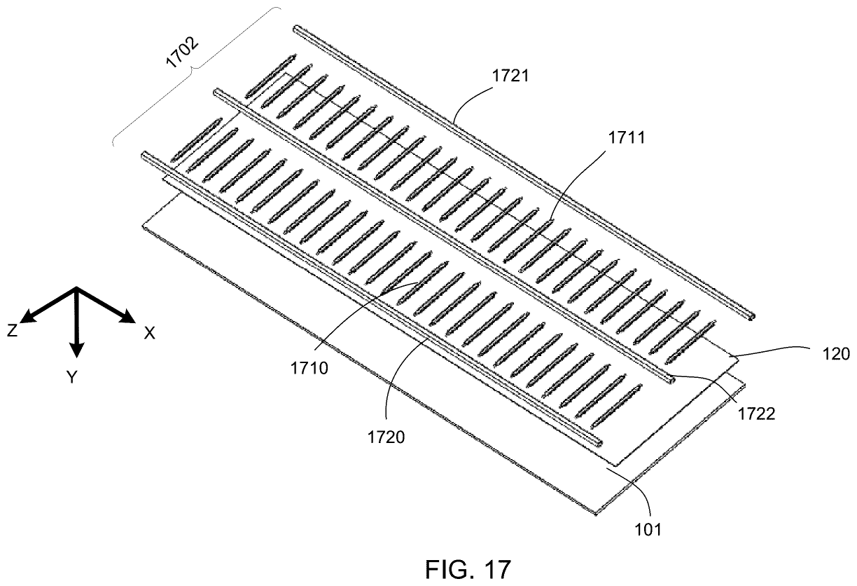

FIG. 16 illustrates a perspective view of a PVT system 200 attached to a solar panel 101, according to a seventh embodiment. FIG. 17 illustrates a bottom exploded view of the thermal parts 1702 used with a solar panel 101, without showing an insulating layer, according to the seventh embodiment. Referring to FIGS. 16 and 7, the thermal parts 1702 include a first manifold 1720 positioned proximate to a top edge of the solar panel 101 or the top edge of the solar cells 111, a second manifold 1721 positioned proximate to a bottom edge of the solar panel 101 or the bottom edge of the solar cells 111, and a third manifold 1722 positioned between the first manifold 1720 and the second manifold 1721. A first plurality of heat pipes 1710 is coupled to the first manifold 1720 and the third manifold 1722. A second plurality of heat pipes 1711 is coupled to the second manifold 1721 and third manifold 1722. This configuration of manifolds 1720, 1721, 1722 and heat pipes 1710, 1711 changes the direction of the heat flux from across the back of the solar panel 101 inwards, utilizing multiple manifolds 1720, 1721, 1722 to support the direction of heat flow into and out of the heat pipes 1710, 1711. The configuration illustrated in FIG. 17 may be used to provide either cooling or heating as needed. In warmer months, the configuration of FIG. 17 may be used to transfer heat out of the heat pipes 1710, 1711 and to the two peripheral manifolds 1720, 1721 to cool the solar cells. In the colder months, the configuration of FIG. 17 may be used to supply heat through the middle manifold 1722 to the solar panel 101 to melt any snow residing on the solar panel 101.

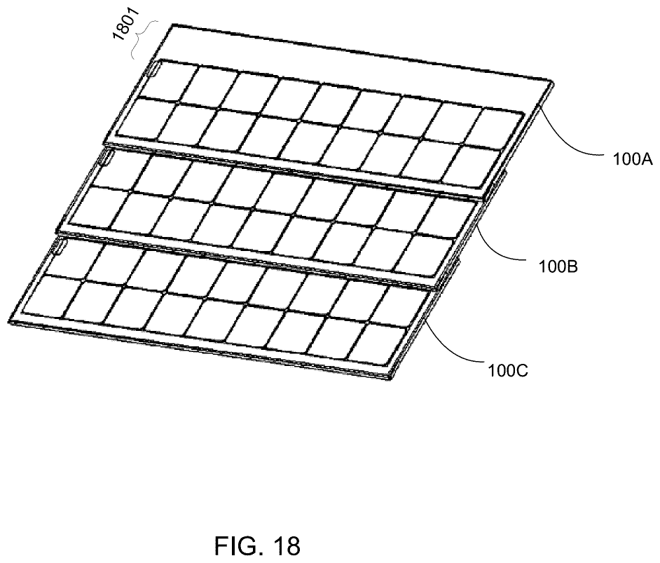

FIG. 18 illustrates a first configuration of a plurality of PVT systems 100A, 100B, 100C. In the first configuration, a portion 1801 of each solar panel in each PVT system overlaps an adjacent PVT system. For example, a portion 1801 of the PVT system 100C overlaps with the adjacent PVT system 100B, where the portion 1801 of the PVT system 100C resides under the PVT system 100B. Similarly, a portion 1801 of the PVT system 100B resides under the adjacent PVT system 100A. In this manner, the PVT systems 100A, 100B, 100C may be installed to provide a “shingled” aesthetic to a structure.

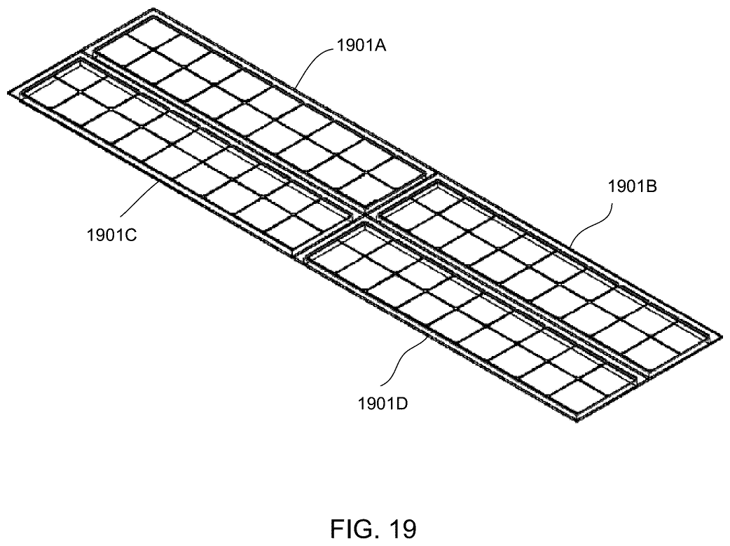

FIG. 19 illustrates a second configuration of a plurality of PVT system 1901A, 1901B, 1901C, 1901D. In the second configuration, the PVT systems 1901A, 1901B, 1901C, 1901D reside flush with each other and do not overlap. In contrast to the PVT systems 100A, 100B, and 100C in the first configuration, each PVT system 1901A, 1901B, 1901C, 1901D in the second configuration does not include the portion 1801. In this manner, the PVT systems 1901A, 1901B, 1901C, 1901D may be installed to provide a “flush” aesthetic to a structure.

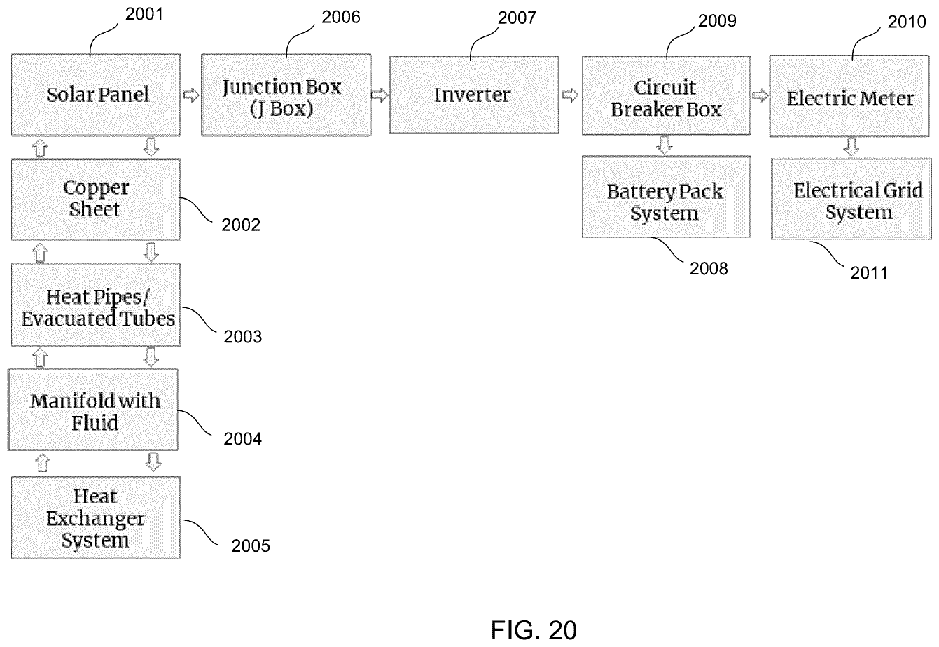

FIG. 20 illustrates an example system that utilizes the PVT system 100. Heat may be collected from the solar panel 2001 (e.g., solar panel 101), transferred to the copper sheet 2002 (e.g., copper sheet 120), then to heat pipes or evacuated heat tubes 2003 (e.g., heat pipes 1301 or evacuated tube 1401), then to the manifold with fluid 2004 (e.g., manifold 122, 810, 1220, 1721, and/or 1722), then to a heat exchanger system 2005. The PVT system 100 includes a junction box 2006 (e.g., junction box 601) which is connected to an inverter 2007, which is connected to a circuit breaker box 2009. The circuit breaker box 2009 can also be connected to a battery pack system 2008 or an electric meter 2010, and from there, to the electrical grid system 2011.

FIG. 21 illustrates an example ecosystem that uses the PVT system 100. The example ecosystem may be a solar geothermal house with a pool, as illustrated in FIG. 22. Referring to FIGS. 21 and 22, a plurality of PVT systems may be “building integrated”, where an array of PVT systems 2001 function as a roof of a house. Heat generated by the array 2001, through exposure of the solar cells to the sun, is collected and transferred to a heat exchanger system 2005 in a utility room. Heat from an enhanced geothermal well system 2101 is collected and transferred to the heat exchanger system 2005 as well. The heat exchanger system 2005 indirectly transfers the heat to wall panels 2102 inside one or more rooms to heat the rooms. The heat exchanger system 2005 further indirectly transfers heat to a pool 2103 to heat the water in the pool 2103. In warmer months, this process can be reversed, such that heat may be collected from the wall panels 2102 inside the rooms, and transferred to the heat exchanger system 2005, and heat from the heat exchanger system 2005 may be transferred to the geothermal well 2101, cooling the house. In colder months, heat from the geothermal well 2101 may be transferred to the array 2001 to melt may accumulated snow on the array 2001, and to the wall panels 2102 to heat the house. The array 2001 may be connected to batteries 2008 to store electricity for use when there is not enough sunlight to harvest, such as during nighttime. The array 2001 may also be connected to the electrical grid system 2009, from which electricity may be drawn when there is not enough sunlight to harvest.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Also, as used herein, “or” as used in a list of items (possibly prefaced by “at least one of” or prefaced by “one or more of”) indicates a disjunctive list such that, for example, a list of “at least one of A, B, or C,” or a list of “one or more of A, B, or C” or a list of “A or B or C” means A, or B, or C, or AB (A and B), or AC (A and C), or BC (B and C), or ABC (i.e., A and B and C), or combinations with more than one feature (e.g., AA, AAB, ABBC, etc.).

The systems and devices discussed above are examples. Various configurations may omit, substitute, or add various procedures or components as appropriate. For instance, features described with respect to certain configurations may be combined in various other configurations. Different aspects and elements of the configurations may be combined in a similar manner. Also, technology evolves and, thus, many of the elements are examples and do not limit the scope of the disclosure or claims.

Unless otherwise indicated, “about” and/or “approximately” as used herein when referring to a measurable value such as an amount, a temporal duration, and the like, encompasses variations of ±20% or ±10%, ±5%, or ±0.1% from the specified value, as appropriate in the context of the systems, devices, circuits, methods, and other implementations described herein. Unless otherwise indicated, “substantially” as used herein when referring to a measurable value such as an amount, a temporal duration, a physical attribute (such as frequency), and the like, also encompasses variations of ±20% or ±10%, ±5%, or ±0.1% from the specified value, as appropriate in the context of the systems, devices, circuits, methods, and other implementations described herein.

### Implementation Examples

Without limitation, potential subject matter that may be claimed (prefaced with the letter “P” so as to avoid confusion with the actual claims presented below) includes:

P1. A photovoltaic thermal system for coupling to a solar panel, comprising: thermal parts, comprising: a copper sheet comprising a first side and a second side opposite the first side, wherein the first side is for coupling to a back of the solar panel; at least a first plurality of heat pipes coupled to the second side of the copper sheet; and at least a first manifold coupled to ends of the first plurality of heat pipes; and an insulation layer coupled to the thermal parts, wherein if the thermal parts are coupled to the back of the solar panel, the copper sheet receives heat transferred from the solar panel and transfers the heat to the first plurality of heat pipes, and the first plurality of heat pipes transfers the heat to the first manifold.

P2. The system of P1, wherein the first manifold transfers the heat to a fluid circulation system.

P3. The system of P1, wherein if the thermal parts are coupled to the back of the solar panel, the first manifold is positioned proximate to a top edge of the solar panel.

P4. The system of P1, wherein if the thermal parts are coupled to the back of the solar panel, the first manifold is positioned proximate to a top edge of at least one solar cell in the solar panel.

P5. The system of P1, wherein the first manifold comprises a plurality of entrances, wherein each of the first plurality of heat pipes comprises a bulb, wherein the bulbs of the first plurality of heat pipes are coupled to the plurality of entrances, wherein fluid that flows through the first manifold contacts the bulbs.

P6. The system of P1, wherein the first plurality of heat pipes are arranged to maximize an amount of heat transferred from a plurality of solar cells in the solar panel.

P7. The system of P5, wherein a plurality of solar cells in the solar panel are configured in a plurality of columns, wherein the first plurality of heat pipes are configured in sets of heat pipes, wherein each set of heat pipes corresponds to a column of the plurality of columns.

P8. The system of P6, wherein a number of heat pipes in each set of heat pipes is based on a target managed temperature for the plurality of solar cells.

P9. The system of P2, wherein the thermal parts further comprise a second manifold positioned proximate to a bottom edge of the solar panel, wherein each of the first plurality of heat pipes is coupled to the first manifold at a first end and coupled to the second manifold at a second end.

P10. The system of P9, wherein if the thermal parts are coupled to the back of the solar panel, the second manifold transfers heat to the first plurality of heat pipes, the first plurality of heat pipes transfers the heat to the copper sheet, and the copper sheet transfers the heat to the solar panel.

P11. The system of P8, wherein the thermal parts further comprise a third manifold, wherein the third manifold is positioned between the first manifold and the second manifold.

P12. The system of P10, wherein the thermal parts further comprise a second plurality of heat pipes, wherein the first plurality of heat pipes is coupled to the first manifold and the third manifold, wherein the second plurality of heat pipes is coupled to the second manifold and the third manifold.

P13. The system of P1, wherein the copper sheet comprises dimensions that approximately match dimensions of the solar panel.

P14. The system of P1, wherein the first manifold comprises a plurality of guiding channels along a length of the first manifold, wherein each guiding channel comprises an intersection, wherein a bulb of a heat pipe of the first plurality of heat pipes mechanically couples to the intersection without using an adhesive.

P15. The system of P1, wherein each of the first plurality of heat pipes comprises a wick-structure flat heat pipe.

P16. The system of P1, wherein each of the first plurality of heat pipes comprises a round evacuated tube.

P17. The system of P1, wherein the photovoltaic system is coupled to the back of the solar panel and integrated into a structure of a building.

P18. The system of P1, wherein the insulating layer comprises an insulating foam molded over the thermal parts and the back of the solar panel.

P19. A system, comprising: a solar panel comprising a plurality of solar cells; and a photovoltaic thermal system coupled to a back of the solar panel, the photovoltaic thermal system comprising: a copper sheet comprising a first side and a second side opposite the first side, wherein the first side is for coupling to a back of the solar panel; a plurality of heat pipes coupled to the second side of the copper sheet; and a first manifold coupled to ends of the first plurality of heat pipes and positioned proximate to a top edge of the solar panel; and an insulation layer coupled to the thermal parts, wherein the copper sheet receives heat transferred from the solar panel and transfers the heat to the first plurality of heat pipes, and the first plurality of heat pipes transfers the heat to the first manifold.

P20. The system of P19, wherein the thermal parts further comprise a second manifold positioned proximate to a bottom edge of the solar panel, wherein each of the plurality of heat pipes is coupled to the first manifold at a first end and coupled to the second manifold at a second end, wherein the second manifold transfers heat to the plurality of heat pipes, the plurality of heat pipes transfers the heat to the copper sheet, and the copper sheet transfers the heat to the solar panel.

Various embodiments of the present invention may be characterized by the potential claims listed in the paragraphs following this paragraph (and before the actual claims provided at the end of this application). These potential claims form a part of the written description of this application. Accordingly, subject matter of the following potential claims may be presented as actual claims in later proceedings involving this application or any application claiming priority based on this application. Inclusion of such potential claims should not be construed to mean that the actual claims do not cover the subject matter of the potential claims. Thus, a decision to not present these potential claims in later proceedings should not be construed as a donation of the subject matter to the public.

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. A photovoltaic thermal system for coupling to a solar panel, comprising:
thermal parts, comprising:
a copper sheet comprising a first side and a second side opposite the first side, wherein the first side is for coupling to a back of the solar panel;
at least a first plurality of heat pipes coupled to the second side of the copper sheet; and
at least a first manifold coupled to ends of the first plurality of heat pipes; and
an insulation layer coupled to the thermal parts,
wherein if the thermal parts are coupled to the back of the solar panel, the copper sheet receives heat transferred from the solar panel and transfers the heat to the first plurality of heat pipes, and the first plurality of heat pipes transfers the heat to the first manifold.

2. The system of claim 1, wherein the first manifold transfers the heat to a fluid circulation system.

3. The system of claim 1, wherein if the thermal parts are coupled to the back of the solar panel, the first manifold is positioned proximate to a top edge of the solar panel.

4. The system of claim 1, wherein if the thermal parts are coupled to the back of the solar panel, the first manifold is positioned proximate to a top edge of at least one solar cell in the solar panel.

5. The system of claim 1, wherein the first manifold comprises a plurality of entrances, wherein each of the first plurality of heat pipes comprises a bulb, wherein the bulbs of the first plurality of heat pipes are coupled to the plurality of entrances, wherein fluid that flows through the first manifold contacts the bulbs.

6. The system of claim 1, wherein the first plurality of heat pipes are arranged to maximize an amount of heat transferred from a plurality of solar cells in the solar panel.

7. The system of claim 5, wherein a plurality of solar cells in the solar panel are configured in a plurality of columns, wherein the first plurality of heat pipes are configured in sets of heat pipes, wherein each set of heat pipes corresponds to a column of the plurality of columns.

8. The system of claim 6, wherein a number of heat pipes in each set of heat pipes is based on a target managed temperature for the plurality of solar cells.

9. The system of claim 2, wherein the thermal parts further comprise a second manifold positioned proximate to a bottom edge of the solar panel, wherein each of the first plurality of heat pipes is coupled to the first manifold at a first end and coupled to the second manifold at a second end.

10. The system of claim 9, wherein if the thermal parts are coupled to the back of the solar panel, the second manifold transfers heat to the first plurality of heat pipes, the first plurality of heat pipes transfers the heat to the copper sheet, and the copper sheet transfers the heat to the solar panel.

11. The system of claim 8, wherein the thermal parts further comprise a third manifold, wherein the third manifold is positioned between the first manifold and the second manifold.

12. The system of claim 10, wherein the thermal parts further comprise a second plurality of heat pipes, wherein the first plurality of heat pipes is coupled to the first manifold and the third manifold, wherein the second plurality of heat pipes is coupled to the second manifold and the third manifold.

13. The system of claim 1, wherein the copper sheet comprises dimensions that approximately match dimensions of the solar panel.

14. The system of claim 1, wherein the first manifold comprises a plurality of guiding channels along a length of the first manifold, wherein each guiding channel comprises an intersection, wherein a bulb of a heat pipe of the first plurality of heat pipes mechanically couples to the intersection without using an adhesive.

15. The system of claim 1, wherein each of the first plurality of heat pipes comprises a wick-structure flat heat pipe.

16. The system of claim 1, wherein each of the first plurality of heat pipes comprises a round evacuated tube.

17. The system of claim 1, wherein the photovoltaic system is coupled to the back of the solar panel and integrated into a structure of a building.

18. The system of claim 1, wherein the insulating layer comprises an insulating foam molded over the thermal parts and the back of the solar panel.

19. A system, comprising:
a solar panel comprising a plurality of solar cells; and
a photovoltaic thermal system coupled to a back of the solar panel, the photovoltaic thermal system comprising:
a copper sheet comprising a first side and a second side opposite the first side, wherein the first side is for coupling to a back of the solar panel;
a plurality of heat pipes coupled to the second side of the copper sheet; and
a first manifold coupled to ends of the first plurality of heat pipes and positioned proximate to a top edge of the solar panel; and
an insulation layer coupled to the thermal parts,
wherein the copper sheet receives heat transferred from the solar panel and transfers the heat to the first plurality of heat pipes, and the first plurality of heat pipes transfers the heat to the first manifold.

20. The system of claim 19, wherein the thermal parts further comprise a second manifold positioned proximate to a bottom edge of the solar panel, wherein each of the plurality of heat pipes is coupled to the first manifold at a first end and coupled to the second manifold at a second end, wherein the second manifold transfers heat to the plurality of heat pipes, the plurality of heat pipes transfers the heat to the copper sheet, and the copper sheet transfers the heat to the solar panel.
